(19) United States
(12) Patent Application Publication
(10) Pub. No.: US 2024/0107639 A1
(43) Pub. Date: Mar. 28, 2024

(54) THERMAL PROCESSING APPARATUS USING MICROWAVE AND OPERATION METHOD THEREOF

(71) Applicant: SEMES CO., LTD., Cheonan-si (KR)

(72) Inventors: Han Lim KANG, Seoul (KR); Yoon Seok CHOI, Suwon-si (KR); Yun Sang KIM, Seongnam-si (KR); Hyun Woo JO, Hwaseong-si (KR); Sang Jeong LEE, Hwaseong-si (KR)

(73) Assignee: SEMES CO., LTD., Cheonan-si (KR)

(21) Appl. No.: 18/203,669

(22) Filed: May 31, 2023

(30) Foreign Application Priority Data
Sep. 22, 2022 (KR) 10-2022-0120125

(51) Int. Cl. H05B 6/80; H05B 6/64; H05B 6/78

(52) U.S. Cl. CPC H05B 6/80; H05B 6/6455; H05B 6/78; H05B 6/707

(57) ABSTRACT

An embodiment of the present disclosure provides a thermal processing apparatus and an operation method thereof capable of controlling a heat distribution of a substrate at a low cost in a thermal processing process using a microwave. According to the present disclosure, a thermal processing apparatus includes a chamber that forms a thermal processing space of a substrate, a substrate support unit that is located at a lower portion of the thermal processing space and supports the substrate, and a microwave unit that is located at an upper portion of the thermal processing space and forms an electromagnetic field by the microwave in the thermal processing space. The substrate support unit includes a chuck fixed at the lower portion of the thermal processing space, a lifting drive mechanism configured to support the substrate with raising and lowering the substrate with respect to the chuck, and a controller that controls the lifting drive mechanism to adjust a height of the substrate based on a temperature distribution for each area of the substrate.

### CROSS-REFERENCE TO RELATED APPLICATION

The present application claims priority to Korean Patent Application No. 10-2022-0120125, filed on Sep. 22, 2022, the entire contents of which is incorporated by reference herein for all purposes.

### BACKGROUND

### Field of the Invention

The present disclosure relates to a thermal processing apparatus using a microwave and an operation method thereof.

### Description of the Related Art

A semiconductor manufacturing process is a process of manufacturing a final product through tens to hundreds of processing processes on a substrate (wafer), and can be executed by a manufacturing facility that performs each process. In the semiconductor manufacturing process, a thermal processing process of controlling a chemical reaction for substrate processing by applying heat energy to the substrate. In particular, a substrate thermal processing method of applying heat energy to a substrate by using electromagnetic waves in a microwave band may be used.

In the middle of applying electromagnetic waves in the microwave band to the substrate, the heat energy applied for each area of the substrate may differ in accordance with the distribution of an electromagnetic field. In the related art, in order to control the heat distribution of the substrate, a method of controlling the intended heat transfer distribution by changing the design of an antenna that emits microwaves is mainly used. The distribution of the electromagnetic field and the heat transfer profile of the substrate may change depending on process conditions or the structure of a chamber, and unnecessary costs may be required because the antenna needs to be redesigned every time in accordance with the process conditions.

### SUMMARY

An embodiment of the present disclosure provides a thermal processing apparatus and an operation method thereof capable of controlling a heat distribution of a substrate at a low cost in a thermal processing process using a microwave.

According to an embodiment of the present disclosure, a thermal processing apparatus includes a chamber that forms a thermal processing space of a substrate, a substrate support unit that is located at a lower portion of the thermal processing space and supports the substrate, and a microwave unit that is located at an upper portion of the thermal processing space and forms an electromagnetic field by the microwave in the thermal processing space. The substrate support unit includes a chuck fixed at the lower portion of the thermal processing space, a lifting drive mechanism configured to support the substrate with raising and lowering the substrate with respect to the chuck, and a controller that controls the lifting drive mechanism to adjust a height of the substrate based on a temperature distribution for each area of the substrate.

According to the embodiment of the present disclosure, the microwave unit may include a microwave generator that generates a microwave signal, a waveguide that transmits the microwave signal, and an antenna that forms an electromagnetic field by the microwave in the thermal processing space from the microwave signal transmitted through the waveguide.

According to the embodiment of the present disclosure, the lifting drive mechanism may raise or lower the substrate by a plurality of lifting pins that support the lower portion of the substrate.

According to the embodiment of the present disclosure, the lifting drive mechanism may raise or lower the substrate by a ring structure that supports the lower portion of the substrate.

According to the embodiment of the present disclosure, the controller may determine a heating area based on a difference between the temperature distribution for each area of the substrate and a target temperature distribution, and position the substrate at a height corresponding to the heating area.

According to the embodiment of the present disclosure, the controller may determine the height corresponding to the heating area by using map data indicating a substrate temperature change in accordance with the height of the substrate.

According to the embodiment of the present disclosure, the map data indicating the substrate temperature change in accordance with the substrate height may be learned and updated through simulation or experimental data.

According to the embodiment of the present disclosure, the temperature distribution for each area of the substrate may be obtained from thermal distribution image data capture by a thermal imaging camera located above the substrate.

According to the embodiment of the present disclosure, the temperature distribution for each area of the substrate may be obtained by a temperature sensor provided in the lifting drive mechanism.

According to another embodiment of the present disclosure, there is provided an operation method of a thermal processing apparatus using a microwave. The operation method includes applying the microwave to a substrate, measuring a temperature distribution for each area of the substrate, and adjusting a height of the substrate in accordance with the temperature distribution for each area of the substrate.

According to the embodiment of the present disclosure, the adjusting of the height may include determining a heating area based on a difference between the temperature distribution for each area of the substrate and a target temperature distribution, determining a height corresponding to the heating area by using map data indicating a substrate temperature change in accordance with the height of the substrate, and positioning the substrate at the height corresponding to the heating area.

According to the embodiment of the present disclosure, the map data indicating the substrate temperature change in accordance with the substrate height may be learned and updated through simulation or experimental data.

According to the embodiment of the present disclosure, the adjusting of the height may further include obtaining temperature change data for each area of the substrate in accordance with adjustment of the height, and updating the map data by using the temperature change data for each area of the substrate.

According to still another embodiment of the present disclosure, a thermal processing apparatus using a microwave includes a chamber that forms a thermal processing space of a substrate, a substrate support unit that is located at a lower portion of the thermal processing space and supports the substrate, and a microwave unit that is located at an upper portion of the thermal processing space and forms a microwave electromagnetic field in the thermal processing space. The substrate support unit may include a chuck fixed at the lower portion of the thermal processing space, a lifting drive mechanism that supports the substrate with raising and lowering the substrate with respect to the chuck, and a controller that controls the lifting drive mechanism to adjust a height of the substrate based on a temperature distribution for each area of the substrate. The controller may determine a heating area based on a difference between the temperature distribution for each area of the substrate and a target temperature distribution, determine the height corresponding to the heating area by using map data indicating a substrate temperature change in accordance with the height of the substrate, position the substrate at the height corresponding to the heating area, and updates the map data by using a temperature change measurement value of the substrate in accordance with adjustment of the height.

According to the embodiment of the present disclosure, the controller may obtain temperature change data for each area of the substrate in accordance with adjustment of the height, and update the map data by using the temperature change data for each area of the substrate.

The effects of the present disclosure are not limited to the effects described above, and effects not mentioned can be clearly understood by those skilled in the art, from the specification and the attached drawings.

### BRIEF DESCRIPTION OF THE DRAWINGS

The above and other objectives, features, and other advantages of the present disclosure will be more clearly understood from the following detailed description taken in conjunction with the accompanying drawings, in which:

FIG. 1 illustrates a schematic structure of a thermal processing apparatus using a microwave according to the present disclosure;

FIG. 2 illustrates an example of a partitioned substrate area for thermal processing according to the present disclosure;

FIG. 3 illustrates a case in which a lifting pin is applied for lifting a substrate in the thermal processing apparatus using the microwave according to the present disclosure;

FIG. 4 illustrates an example of a portion at which the substrate is supported when the substrate is lifted by using a lifting pin in the thermal processing apparatus using the microwave according to the present disclosure.

FIG. 5 illustrates an example in which a ring structure is applied for lifting a substrate in the thermal processing apparatus using the microwave according to the present disclosure;

FIG. 6 illustrates an example of the ring structure for lifting the substrate in the thermal processing apparatus using the microwave according to the present disclosure;

FIGS. 7 to 9 are diagrams illustrating a process of controlling a height of the substrate for adjusting a temperature for each area of the substrate in the thermal processing apparatus using the microwave according to the present disclosure;

FIG. 10 illustrates a structure of a chamber equipped with a thermal imaging camera for measuring the temperature of the substrate in the thermal processing apparatus using the microwave according to the present disclosure;

FIG. 11 illustrates a case in which a temperature sensor for measuring the temperature for each area of the substrate is mounted on the lifting pin in the thermal processing apparatus using the microwave according to the present disclosure;

FIG. 12 illustrates a case in which a temperature sensor for measuring the temperature for each area of the substrate is mounted on the ring structure in the thermal processing apparatus using the microwave according to the present disclosure; and

FIG. 13 is a flowchart illustrating an operation method of the thermal processing apparatus using the microwave.

### DETAILED DESCRIPTION

Hereinafter, embodiments of the present disclosure will be described in detail with reference to the attached drawings to be easily implemented by those skilled in the art. The present disclosure may be implemented in various different forms and is not limited to the embodiments described herein.

In order to clearly describe the present disclosure, parts that are not related to the description will be omitted, and the same or similar components in this specification are denoted by the same reference sign.

In addition, in various embodiments, a component having the same configuration will be described only in a representative embodiment by using the same reference sign, and only a configuration that is different from that of the representative embodiment will be described in other embodiments.

In the entirety of this specification, a sentence that a portion is “connected (or coupled) to” another portion includes not only a case of “being directly connected (coupled)” but also a case of “being indirectly connected (coupled) with other members interposed therebetween”. In addition, a sentence that a portion “includes” a component means that it may further include another component rather than excluding other components unless a particularly opposite statement is made.

Unless otherwise defined, all terms used herein, including technical or scientific terms, have the same meaning as generally understood by those skilled in the art. Terms such as those defined in a commonly used dictionary should be construed as having a meaning consistent with the meaning of the relevant technology, and should not be construed as an ideal or excessively formal meaning unless explicitly defined in this application.

Hereinafter, a thermal processing apparatus 1 using a microwave and an operation method thereof according to the present disclosure will be described. In this document, a case where an apparatus that performs thermal processing on a substrate uses electromagnetic waves of microwaves will be mainly described, but the scope of the present disclosure is not limited thereto, and can be applied to various methods for performing thermal processing on a substrate. The microwave is an electromagnetic wave having a wavelength that is shorter than radio waves and longer than infrared rays, and refers to an electromagnetic wave having a wavelength of 1 mm to 1 m.

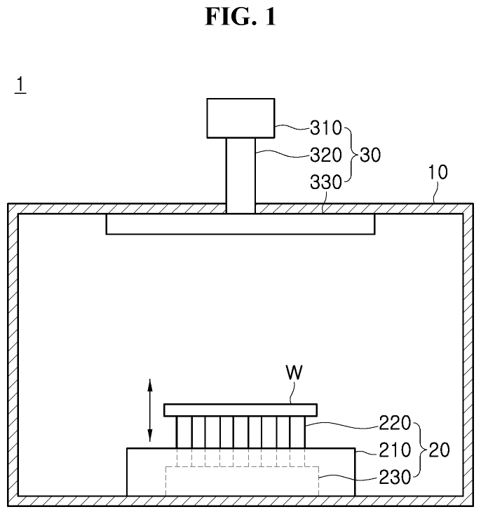

FIG. 1 illustrates a schematic structure of the thermal processing apparatus 1 using a microwave according to the present disclosure; The thermal processing apparatus 1 according to the present disclosure includes a chamber 10 that forms a thermal processing space of a substrate W, a substrate support unit 20 that is located at the lower portion of the thermal processing space and supports the substrate W, and a microwave unit 30 that is located at the upper portion of the thermal processing space and applies microwaves to the substrate W.

The chamber 10 forms a space in which the thermal processing process of the substrate W is performed, and separates the thermal processing space of the substrate W from the outer space. The substrate support unit 20 that supports the substrate W may be provided at the lower portion of the chamber 10, and the microwave unit 30 may be provided at the upper portion of the chamber 10.

The substrate support unit 20 includes a chuck 210 fixed at the lower portion of the thermal processing space, a lifting drive mechanism 220 that supports the substrate W with raising and lowering the substrate W with respect to the chuck 210, and a controller 230 that controls the lifting drive mechanism 220 to adjust a height of the substrate W based on a temperature distribution for each area of the substrate W. According to the present disclosure, the height of the substrate W is adjusted by the lifting drive mechanism 220. Since the distribution of heat energy applied to the substrate W varies depending on the height of the substrate W, the temperature of each area of the substrate W can be adjusted by adjusting the height of the substrate W.

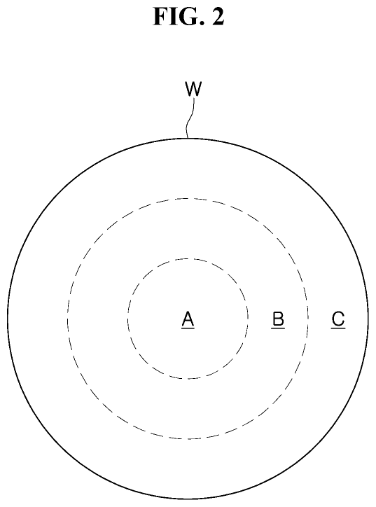

The area separation of the substrate W may be variously made as necessary. In this document, an example in which thermal processing is performed by dividing the substrate W into three areas as illustrated in FIG. 2 will be described. With reference to FIG. 2, the substrate W may be divided into a first area A, a second area B, and a third area C based on the center point, and a method of adjusting the lifting height of the substrate W in order to control the temperature of each area will be described.

The microwave unit 30 includes a microwave generator 310 that generates a microwave signal, a waveguide 320 that transmits a microwave signal, and an antenna 330 that forms a microwave electromagnetic field in the thermal processing space from the microwave signal transmitted through the waveguide 320. The microwave generator 310 generates a microwave signal having a frequency of several tens of gigahertz (for example, 23 GHz to 26 GHz), and the microwave signal is transmitted to the antenna 330 through the waveguide 320. Here, the waveguide 320 may have a polygonal tubular shape, and the inner side may be made of a conductor (for example, gold and silver). The antenna 330 emits the microwave signal into the thermal processing space, and the microwave signal may be transmitted to the thermal processing space through a slot and a transmission plate formed in the antenna 330. An electromagnetic field is formed in the thermal processing space by the microwave signal, and thermal processing on the substrate W can be performed by the energy of the electromagnetic field.

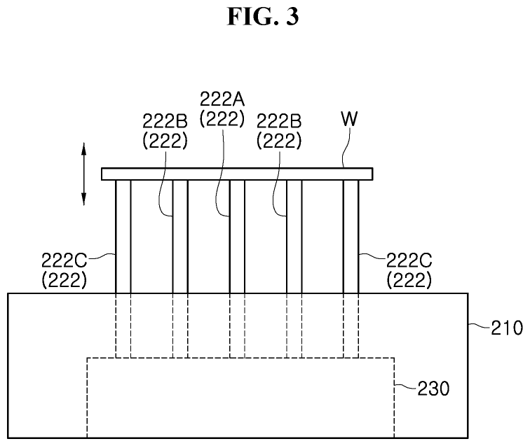

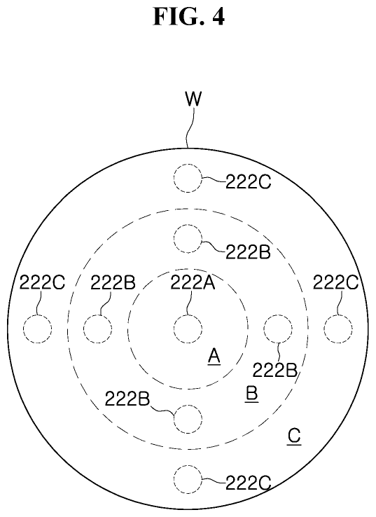

According to the embodiment of the present disclosure, the lifting drive mechanism 220 may raise or lower the substrate by a plurality of lifting pins 222 that support the lower portion of the substrate W. The lifting drive mechanism 220 may be configured by the lifting pin 222 capable of raising and lowering the substrate W while supporting the substrate W, by coming into contact with the lower portion of the substrate W. With reference to FIGS. 3 and 4, a first lifting pin 222A that supports the first area A of the substrate W, a second lifting pin 222B that supports the second area B of the substrate W, and a third lifting pin 222C that supports the third area C of the substrate W may support the substrate W, respectively. The lifting pins 222 may individually or integrally perform the raising and lowering drive, and the raising and lowering drive may be performed by a drive device such as a linear motor, a cylinder, and a ball screw.

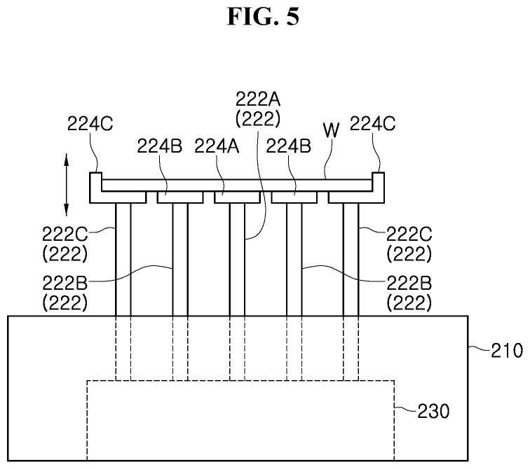

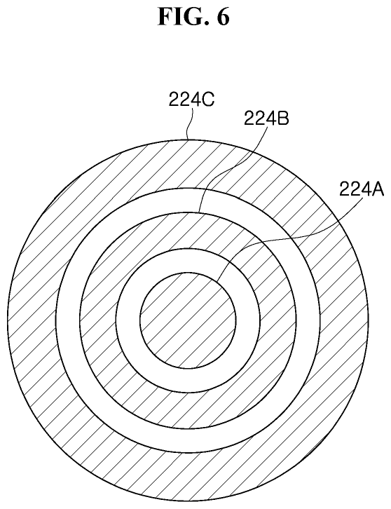

According to the present disclosure, the lifting drive mechanism 220 may raise or lower the substrate W by a ring structure 224 that supports the lower portion of the substrate W. The lifting drive mechanism 220 may include the ring structure 224 that supports the lower portion of the substrate W and the plurality of lifting pins 222 that raise or lower the ring structure 224. With reference to FIGS. 5 and 6, the ring structure 224 may be configured by a plurality of substructures that support the respective areas of the substrate W. The ring structure 224 includes a first ring structure 224A that supports a first area A of the substrate W, a second ring structure 224B that supports the second area B of the substrate W, and a third ring structure 224C that supports the third area C of the substrate W. The first ring structure 224A is supported by the first lifting pin 222A, the second ring structure 224B is supported by the second lifting pin 222B, and the third ring structure 224C is supported by the third lifting pin 222C. The lifting pins 222 may be configured to rise or fall individually or integrally.

According to the present disclosure, the controller 230 may determine a heating area based on a difference between the temperature distribution for each area of the substrate W and a target temperature distribution, and position the substrate W at a height corresponding to the heating area. For example, when there is a target temperature for the thermal processing process of the substrate W, the temperature for each area of the substrate W may be different depending on an electromagnetic field distribution. At this time, when intensive heating is required for a specific area, precise thermal processing on the substrate W can be performed by adjusting the height of the substrate W.

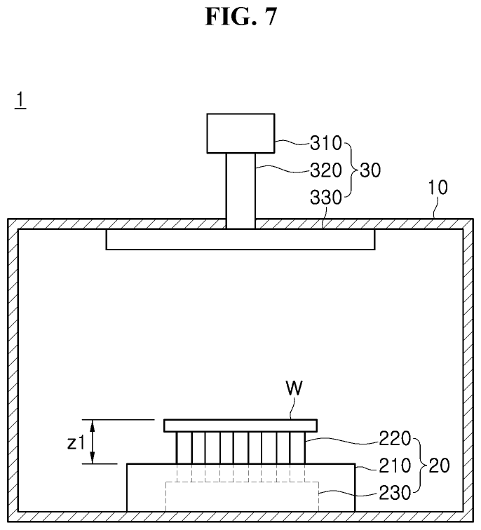

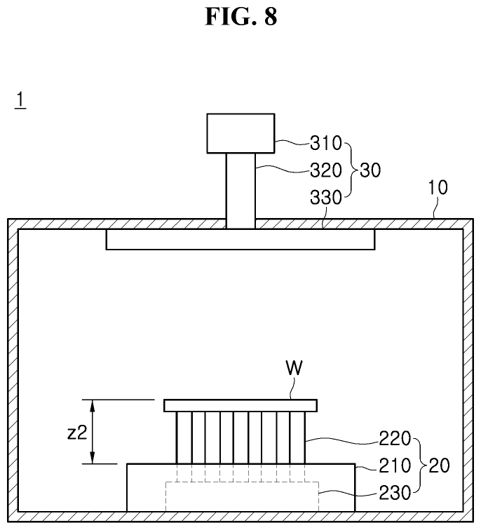

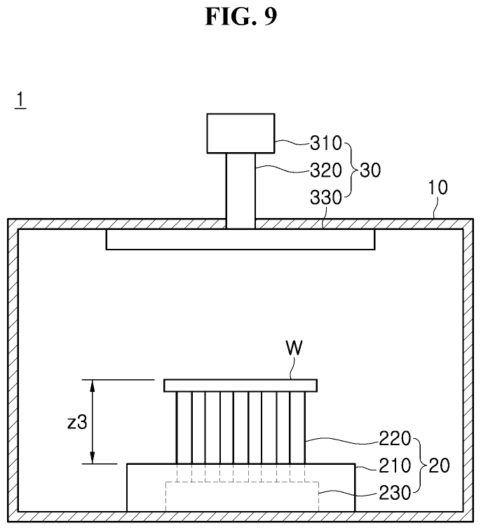

For example, when intensive heating of the first area A of the substrate W is required as illustrated in FIG. 7, the controller 230 may position the substrate W at a first height z1. When intensive heating of the second area B of the substrate W is required as illustrated in FIG. 8, the controller 230 may position the substrate W at a second height z2. In addition, when intensive heating to the third area C of the substrate W is required as illustrated in FIG. 9, the controller 230 may position the substrate W at a third height z3. The controller 230 may control the raising and lowering drive of the lifting drive mechanism 220 in accordance with the target height of the substrate W.

According to the present disclosure, the controller 230 may determine the height corresponding to the heating area by using map data indicating a substrate temperature change in accordance with the height of the substrate. The map data may be data that stores a lifting height suitable for a target area and a target temperature change amount of the substrate W. The map data indicating the substrate temperature change in accordance with the height of the substrate may be learned and updated through simulation or experimental data.

In addition, when the thermal processing is completed by the controller 230, the map data may be updated by using a temperature change measurement value of the substrate W in accordance with the adjustment of the height of the substrate W. The controller 230 may obtain temperature change data for each area of the substrate W in accordance with the adjustment of the height, and update the map data by using the temperature change data for each area of the substrate W. It is possible to construct more accurate map data by measuring the temperature change for each area of the substrate W in accordance with the adjustment of the height of the substrate W and updating the map data as described above.

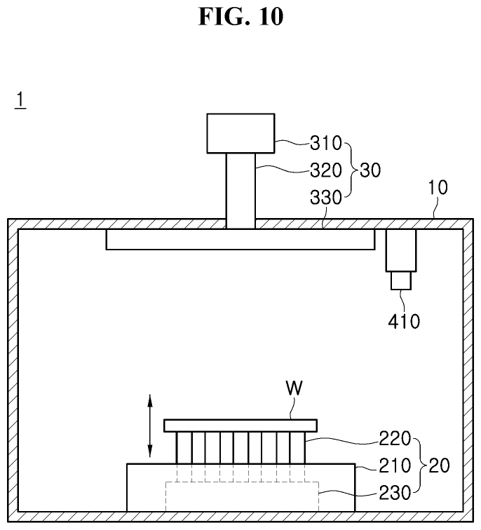

According to the present disclosure, the temperature distribution for each area of the substrate W may be obtained from thermal distribution image data capture by a thermal imaging camera 410 located above the substrate W. With reference to FIG. 10, the thermal imaging camera 410 may be provided in the upper area of the chamber 10. The thermal imaging camera 410 may emit a signal of an infrared wavelength to the substrate W and measure the reflected signal to generate an image indicating the temperature distribution of the substrate W. In addition to the thermal imaging camera, the temperature of the substrate W may be measured by various non-contact temperature measuring devices.

According to the present disclosure, the temperature distribution for each area of the substrate W may be obtained by a temperature sensor 420 provided in the lifting drive mechanism 220. The temperature sensor 420 may be provided in the lifting pin 222 or the ring structure 224 that supports the lower portion of the substrate W.

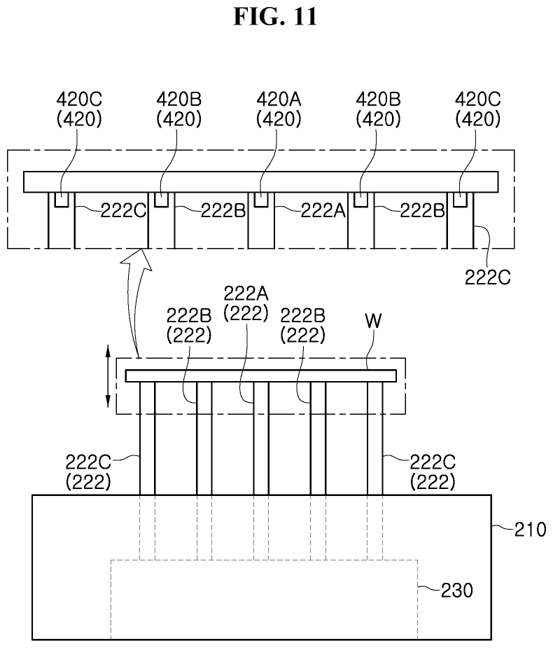

For example, as illustrated in FIG. 11, the temperature sensor 420 may be provided at the end of the lifting pin 222. The first lifting pin 222A includes a first temperature sensor 420A that measures the temperature of the first area A of the substrate W. The second lifting pin 222B include a second temperature sensor 420B that measures the temperature of the second area B of the substrate W. The third lifting pin 222C include a third temperature sensor 420C that measures the temperature of the third area C of the substrate W. Each temperature sensor 420 may be connected to the controller 230 through the internal wiring of the lifting pin 222, and the controller 230 may check the temperature distribution for each area of the substrate W by using the temperature data measured by each temperature sensor 420.

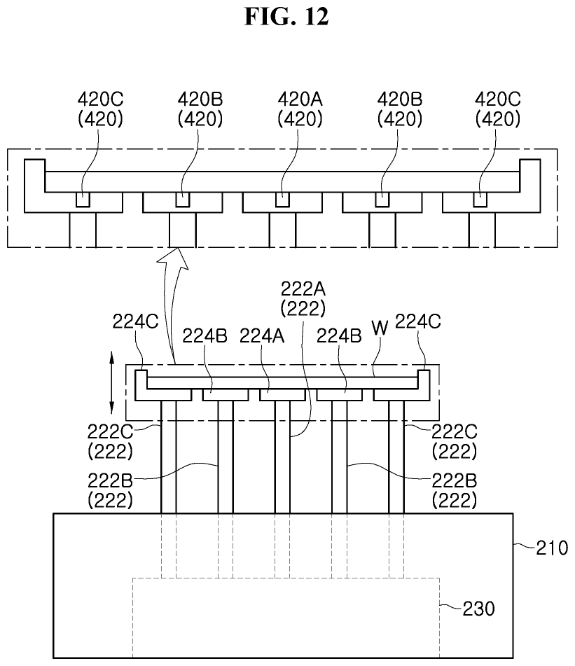

In addition, the temperature sensor 420 may be provided in the ring structure 224 as illustrated in FIG. 12. The first ring structure 224A includes a first temperature sensor 420A that measures the temperature of the first area A of the substrate W. The second ring structure 224B include a second temperature sensor 420B that measures the temperature of the second area B of the substrate W. The third ring structure 224C include a third temperature sensor 420C that measures the temperature of the third area C of the substrate W. Each temperature sensor 420 may be connected to the controller 230 through the internal wirings of the ring structure 224 and the lifting pin 222, and the controller 230 may check the temperature distribution for each area of the substrate W by using the temperature data measured by each temperature sensor 420.

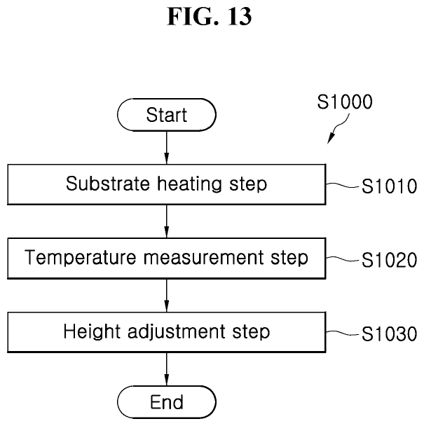

FIG. 13 is a flowchart illustrating an operation method of the thermal processing apparatus 1 using the microwave. The configuration of the thermal processing apparatus 1 may be the same as described with reference to FIGS. 1 to 12. The operation of the thermal processing apparatus 1 may be performed by a processor that is electrically connected to a controller that controls each component including the controller 230. The processor may transmit instructions to cause each controller to perform the intended operation and receive data from the controller.

The operation method of the thermal processing apparatus 1 using the microwave according to the present disclosure includes a substrate heating step S1010 of applying a microwave to a substrate W, a temperature measurement step S1020 of measuring a temperature distribution for each area of the substrate W, and a height adjustment step S1030 of adjusting the height of the substrate W in accordance with the temperature distribution for each area of the substrate W.

The substrate heating step S1010 may be executed by the microwave unit 30. A microwave signal generated by the microwave generator 310 may be transmitted to the antenna 330 through the waveguide 320 and then transmitted to the thermal processing space through the slot and the transmission plate formed in the antenna 330. An electromagnetic field is formed in the thermal processing space by the microwave signal, and thermal processing on the substrate W can be performed by the energy of the electromagnetic field.

The temperature measurement step S1020 is a step of measuring the temperature distribution for each area of the substrate W, and a step of measuring the temperature in a non-contact or contact manner. For example, as illustrated in FIG. 10, the temperature distribution for each area of the substrate W may be obtained from thermal distribution image data capture by a thermal imaging camera 410 located above the substrate W. In addition, as illustrated in FIG. 11 or 12, the temperature distribution for each area of the substrate W may be obtained by the temperature sensor 420 provided in the lifting drive mechanism 220. The temperature sensor 420 may be provided in the lifting pin 222 or the ring structure 224 that supports the lower portion of the substrate W.

According to the embodiment of the present disclosure, the height adjustment step S1030 includes a step of determining a heating area based on a difference between the temperature distribution for each area of the substrate and a target temperature distribution, a step of determining a height corresponding to the heating area by using map data indicating a substrate temperature change in accordance with the height of the substrate, and a step of positioning the substrate at the height corresponding to the heating area.

For example, when there is the target temperature for the thermal processing process of the substrate W, the temperature of each area of the substrate W may be different depending on the distribution of the electromagnetic field. In addition, when intensive heating is required for a specific area, the precise thermal processing of the substrate W may be performed by adjusting the height. As illustrated in FIGS. 7 to 9, the height of the substrate W may be adjusted for precise thermal processing of the substrate W. In this case, the map data indicating a substrate temperature change may be used to adjust the height of the substrate W. The map data is data that stores a lifting height suitable for a target area and a target temperature change amount of the substrate W. The map data may be learned and updated through simulation or experimental data.

According to the present disclosure, the height adjustment step S1030 may further include a step of obtaining temperature change data for each area of the substrate W in accordance with adjustment of the height, and a step of updating the map data by using the temperature change data for each area of the substrate W. It is possible to construct more accurate map data by measuring the temperature change for each area of the substrate W in accordance with the adjustment of the height of the substrate W and updating the map data.

It will be apparent that the present embodiment and the drawings attached to this specification just clearly represent a part of the technical spirit included in the present disclosure, and all modification examples and specific embodiments that can be easily inferred by those skilled in the art within the scope of the technical spirit contained in the specification and drawings of the present disclosure are included in the scope of the present disclosure.

Therefore, the spirit of the present disclosure should not be limited to the described embodiments, and not only the claims to be described later, but also all those that have equal or equivalent modifications to the claims will be said to belong to the scope of the spirit of the present disclosure.

Those skilled in the art should understand that the present disclosure may be embodied in other specific forms without changing the technical spirit or essential characteristics thereof, so the embodiments described above are illustrative in all aspects and are not restrictive.

It will be apparent that the present embodiment and the drawings attached to this specification just clearly represent a part of the technical spirit included in the present disclosure, and all modification examples and specific embodiments that can be easily inferred by those skilled in the art within the scope of the technical spirit contained in the specification and drawings of the present disclosure are included in the scope of the present disclosure.

Therefore, the spirit of the present disclosure should not be limited to the described embodiments, and not only the claims to be described later, but also all those that have equal or equivalent modifications to the claims will be said to belong to the scope of the spirit of the present disclosure.

What is claimed is:

1. A thermal processing apparatus, the thermal processing apparatus comprising:
a chamber that forms a thermal processing space of a substrate;
a substrate support unit that is located at a lower portion of the thermal processing space and supports the substrate; and
a microwave unit that is located at an upper portion of the thermal processing space and emit a microwave signal to form an electromagnetic field in the thermal processing space,
wherein the substrate support unit comprises:
a chuck fixed at the lower portion of the thermal processing space;
a lifting drive mechanism configured to raise or lower the substrate with respect to the chuck; and
a controller that controls the lowering or raising of the lifting drive mechanism to adjust a height of the substrate based on a temperature distribution of the substrate.

2. The thermal processing apparatus according to claim 1,
wherein the microwave unit comprises:
a microwave generator that generates the microwave signal;
a waveguide that transmits the microwave signal; and
an antenna connected to the waveguide and emit the microwave signal to form the electromagnetic field in the thermal processing space.

3. The thermal processing apparatus according to claim 1,
wherein the lifting drive mechanism includes a plurality of lifting pins that support a lower surface of the substrate and raise or lower the substrate.

4. The thermal processing apparatus according to claim 3,
wherein the lifting drive mechanism further includes a ring structure, and
wherein the ring structure include a circular-shape plate, a first ring surrounding the circular-shape plate, and a second ring surrounding the first ring,
wherein the circular-shape plate is connected to at least one of the plurality of lifting pins, the first ring is connected to at least one of the plurality of lifting pins, and the second ring is connected to at least one of the plurality of lifting pins, and
wherein the circular-shape plate, the first ring, and the second ring are concentric.

5. The thermal processing apparatus according to claim 4,
wherein the controller is configured to:
determine a heating area based on a difference between the temperature distribution of the substrate and a target temperature distribution; and
position the substrate at a height corresponding to the heating area.

6. The thermal processing apparatus according to claim 5,
wherein the controller is configured to determine the height corresponding to the heating area by using map data indicating a substrate temperature change in accordance with the height of the substrate.

7. The thermal processing apparatus according to claim 6,
wherein the map data indicating the substrate temperature change in accordance with the height of the substrate is generated through simulation or experimental data.

8. The thermal processing apparatus according to claim 1, further comprising:
a thermal imaging camera located above the wafer and obtaining the temperature distribution for each area of the substrate.

9. The thermal processing apparatus according to claim 1, further comprising:
a temperature sensor provided in the lifting drive mechanism and obtaining the temperature distribution for each of the substrate.

10. An operation method of a thermal processing apparatus using a microwave, the operation method comprising:
applying the microwave to a substrate;
measuring a temperature distribution for the substrate; and
adjusting a height of the substrate in accordance with a temperature distribution for the substrate.

11. The operation method of a thermal processing apparatus according to claim 10, wherein the adjusting of the height comprises:
determining a heating area based on a difference between the temperature distribution for the substrate and a target temperature distribution;
determining a height corresponding to the heating area by using map data indicating a substrate temperature change in accordance with the height of the substrate; and
positioning the substrate at the height corresponding to the heating area.

12. The operation method of a thermal processing apparatus according to claim 11, wherein the map data indicates the substrate temperature change in accordance with the height of the substrate is updated through simulation or experimental data.

13. The operation method of a thermal processing apparatus according to claim 11, wherein the adjusting of the height further comprises:
obtaining temperature change data for the substrate in accordance with adjustment of the height; and
updating the map data by using the temperature change data for the substrate.

14. A thermal processing apparatus using a microwave, the thermal processing apparatus comprising:
a chamber that forms a thermal processing space of a substrate;
a substrate support unit that is located at a lower portion of the thermal processing space and supports the substrate; and
a microwave unit that is located at an upper portion of the thermal processing space and forms a microwave electromagnetic field in the thermal processing space,
wherein the substrate support unit comprises:
a chuck fixed at the lower portion of the thermal processing space,
a lifting drive mechanism configured to support the substrate with raising and lowering the substrate with respect to the chuck, and
a controller that controls the lifting drive mechanism to adjust a height of the substrate based on a temperature distribution for the substrate, and
wherein the controller is configured to:
determine a heating area based on a difference between the temperature distribution for the substrate and a target temperature distribution,
determine a height corresponding to the heating area by using map data indicating a substrate temperature change in accordance with a height of the substrate,
position the substrate at a height corresponding to the heating area, and
update the map data by using a temperature change measurement value of the substrate in accordance with adjustment of the height.

15. The thermal processing apparatus according to claim 14, wherein the microwave unit comprises:
a microwave generator that generates a microwave signal;
a waveguide that transmits the microwave signal; and
an antenna that forms the electromagnetic field by the microwave in the thermal processing space from the microwave signal transmitted through the waveguide.

16. The thermal processing apparatus according to claim 14, wherein the lifting drive mechanism raises or lowers the substrate by a plurality of lifting pins that support a lower portion of the substrate.

17. The thermal processing apparatus according to claim 14, wherein the lifting drive mechanism raises or lowers the substrate by a ring structure that supports a center portion or a side portion of the substrate.

18. The thermal processing apparatus according to claim 14, wherein the temperature distribution for the substrate is obtained from thermal distribution image data capture by a thermal imaging camera located above the substrate.

19. The thermal processing apparatus according to claim 14, wherein the temperature distribution for the substrate is obtained by a temperature sensor provided in the lifting drive mechanism.

20. The thermal processing apparatus according to claim 14, wherein the controller is configured to:
obtain temperature change data for the substrate in accordance with adjustment of the height; and
update the map data by using the temperature change data for the substrate.
